(19) United States
(12) Patent Application Publication
(10) Pub. No.: US 2006/0252196 A1
(43) Pub. Date: Nov. 9, 2006

(54) Semiconductor device and method for producing same

(75) Inventors: Tsuyoshi Serata, Kasaoka-shi (JP); Shuji Enomoto, Nara-shi (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka (JP)

(21) Appl. No.: 11/403,198

(22) Filed: Apr. 13, 2006

(30) Foreign Application Priority Data
Apr. 14, 2005 (JP) 2005-116618

(51) Int. Cl. H01L 21/8238

(52) U.S. Cl. 438/211

(57) ABSTRACT

Above semiconductor substrate 1 via gate insulation film 3, gate electrode 10 is formed having first insulation layer 5 formed on a top surface of gate electrode 10. On semiconductor substrate 1, second insulation layer 7 is formed in such a manner that the side walls of gate electrode 10 and the top surface of first insulation layer 5 are covered. Second insulation layer 7 is etched back in order to form side wall spacers 11 on the side walls of gate electrode 10 and to expose the surface of an element region. First insulation layer 5 is removed off the surface of gate electrode 10. On the surface of semiconductor substrate 1, high-melting-point metal film 8 is formed in such a manner that the top surface of gate electrode 10 and the surfaces of source-drain regions 1b are covered, and thereafter, annealing is carried out thereby siliciding the top surface of gate electrode 10 and the surfaces of source-drain regions 1b in order to form silicide layers 9. According to the present invention, even if the height of the gate electrode is made low, short circuiting between the gate electrode and the source-drain regions is prevented.

### BACKGROUND OF THE INVENTION

The present invention generally relates to a method for producing a semiconductor device, and more particularly to an improved method for producing a semiconductor device such that the thinning of the gate electrode is made possible, the fining of the device structure can be dealt with, and the high integration of the semiconductor device is made possible. The present invention also relates to a semiconductor device that is obtained by such a method.

Currently, for the high speeding of circuit elements, such a technique is used that wiring resistance is reduced by siliciding the element region.

A method for producing a conventional semiconductor device will be described.

Referring to FIG. 14(A), on semiconductor substrate 1, element separating region 2 that divides an element region from other element regions is formed, and thereon, gate insulation film 3 and polysilicon layer 4 are accumulated.

Referring to FIG. 14(B), on the portion that is on polysilicon layer 4 and that corresponds to the portion on which a gate wiring line is formed, resist pattern 6 is formed by the lithography technique. Referring to FIGS. 14(B) and 14(C), using resist pattern 6 as a mask, polysilicon layer 4 and gate insulation film 3 are etched, thereby forming gate electrode 10. Subsequently, resist pattern 6 is removed.

Further, referring to FIG. 14(D), a silicon oxide film is accumulated as insulation layer 7 so as to cover gate electrode 10, which is formed above semiconductor substrate 1.

Referring to FIGS. 14(D) and 15(E), by etching back insulation layer 7, on the side walls of gate electrode 10, side wall spacers 11 of a silicon insulation oxide film for preventing silicidation are left. Subsequently, although not shown, using side wall spacers 11 as masks, impurity ions are implanted, thereby forming a pair of source-drain regions on the surface of semiconductor substrate 1 and at both sides of gate electrode 10.

Referring to FIG. 15(F), on the entire surface of semiconductor substrate 1, a high-melting-point metal such as Ti (titanium), Co (cobalt), and Ni (nickel) is accumulated by the sputtering method, thereby forming high-melting-point metal film 8. Referring to FIG. 15(G), by carrying out silicidation annealing treatment by suitable heat treatment, semiconductor substrate 1 and high-melting-point metal film 8 are allowed to react, and thus, silicided layers 9 are formed. Referring to FIGS. 15(G) and 15(H), if not-yet-reacted high-melting-point metal film of high-melting-point metal film 8 is removed by selective etching, a silicided region and a non-silicided region are formed simultaneously. Although not shown, subsequently, on semiconductor substrate 1, an interlayer insulation film is formed, and in the interlayer insulation film, contact holes that lead to silicided layers 9 are formed. After forming wiring lines, a semiconductor device is completed.

According to this method, referring to FIG. 15(G), at the time of the silicidation annealing treatment, even if the diffusion of silicon from the source-drain regions occurs in high-melting-point metal film 8 on side wall spacers 11, insofar as there is a sufficient distance on the surfaces of side wall spacers 11 between gate electrode 10 and source-drain regions, short circuiting, which is due to the silicided layer, does not occur between gate electrode 10 and the source-drain regions.

However, as the gate wiling line is made fine, the thickness of the gate electrode is becoming thin. FIGS. 16(A)-(D) and FIGS. 17(E)-(H) show the steps of producing a semiconductor device in the case of, when the thickness of the gate electrode is made thin, applying the above-described prior art as it is. In these figures, the parts identical or corresponding to those shown in FIGS. 14(A)-(D) and FIGS. 15(E)-(H) are given the same reference numeral, and descriptions thereof will not be repeated.

In this case, referring to FIG. 16(A), polysilicon layer 4 that is the precursor to the gate electrode is, compared with the above-described prior art, formed thin. In this case, referring to FIG. 17(G), since gate electrode 10 is made thin, on the side surface portions of gate electrode 10, the width of side wall spacers 11 is narrow, and on the surfaces of side wall spacers 11, the distance between gate electrode 10 and the source-drain regions is short. Thus, at the time of the silicidation annealing treatment, if the diffusion of silicon from the source-drain regions occurs in high-melting-point metal film 8 on side wall spacers 11, a thin silicided layer is formed on the surfaces of side wall spacers 11, presenting such a problem that short circuiting occurs between gate electrode 10 and the source-drain regions.

In order to solve the above problem, as a method for making long the distance between gate electrode 10 and the source-drain regions on the side wall spacers, a prior-art technique as shown in FIG. 18 is proposed (for example, Japanese Patent Application Publication No. 08-204193 and Japanese Patent Application Publication No. 08-274043). In these figures, the parts identical or corresponding to those shown in FIGS. 14(A)-(D) and FIGS. 15(E)-(H) are given the same reference numeral, and descriptions thereof will not be repeated.

Referring to FIG. 18(A), on side surfaces of a protruding pattern composed of gate insulation film 3, gate electrode 10, and PSG film pattern 51, side wall spacers 11 of a silicon nitride film are formed. Then, referring to FIG. 18(B), by removing PSG film pattern 51, side wall spacers 11 of a shape that is protruding higher than the height of gate electrode 10 are left. Referring to FIG. 18(C), titanium film 8 is accumulated, and heating treatment with the use of a heating furnace is carried out at a temperature of from 450 to 550° C. for 5-10 minutes. Then, if not-yet-reacted titanium film is removed, referring to FIG. 18(D), a semiconductor device having silicided layers 9 formed on the surface of gate electrode 10 and on the surfaces of the source-drain regions is obtained.

According to this method, by forming side wall spacers 11 of a shape that is protruding higher than the height of gate electrode 10, the distance on the surfaces of side wall spacers 11 between gate electrode 10 and the source-drain regions is made long, and moreover, short circuiting between gate electrode 10 and the source-drain regions is prevented at the siliciding step.

However, in the case of, as in the prior-art method shown in FIG. 18, side wall spacers 11 of a shape that is protruding higher than the height of gate electrode 10, because of physical damage or the like incurred in the cleaning step between the step of removing PSG film 51 off gate electrode 10 and the step of forming the silicided layers, missing of the top portions of side wall spacers 11 occurs, presenting the possibility of occurrence of particles. As a result, there have been such problems that the producing apparatus is contaminated because of the occurrence of particles and that a significant reduction in the yield associated with attachment of particles onto the semiconductor substrate is caused.

### SUMMARY OF THE INVENTION

It is an object of the present invention to provide an improved method for producing a semiconductor device such that even if the height of the gate electrode is made low, short circuiting between the gate electrode and the source-drain regions is prevented.

It is another object of the present invention to provide an improved method for producing a semiconductor device such that short circuiting between the gate electrode and the source-drain regions is prevented without occurrence of particles.

It is still another object of the present invention to provide a semiconductor device obtained by such a method.

In a method for producing a semiconductor device according to a first aspect of the present invention, first, on a surface of a semiconductor substrate, an element separating region for separating an element region from other element regions is formed. Next, above the semiconductor substrate via a gate insulation film, a gate electrode is formed having a first insulation layer formed on the top surface of the gate electrode. On the semiconductor substrate, a second insulation layer is formed in such a manner that side walls of the gate electrode and the top surface of the first insulation layer are covered. The second insulation layer is etched back in order to form side wall spacers on the side walls of the gate electrode and to expose a surface of the element region. With use of the gate electrode and the side wall spacers as masks, impurity ions are implanted into the surface of the element region in order to form a pair of source-drain regions on the surface of the semiconductor substrate and at both sides of the gate electrode. The first insulation layer is removed off the surface of the gate electrode. On the surface of the semiconductor substrate, a high-melting-point metal film is formed in such a manner that the top surface of the gate electrode and the surfaces of the source-drain regions are covered, and thereafter, annealing is carried out thereby siliciding the top surface of the gate electrode and the surfaces of the source-drain regions in order to form silicide layers. Not-yet reacted high-melting-point metal film is removed.

According to this invention, since, on the semiconductor substrate, a second insulation layer, which is the precursor to the side wall spacers, is formed in such a manner that the top surface of the first insulation layer is covered, even if the height of the gate electrode is made low, a sufficient distance is secured between the gate electrode and the source-drain regions on the surfaces of the side wall spacers.

According to a preferred embodiment of the present invention, the step of removing the first insulation layer off the top surface of the gate electrode is carried out by wet etching treatment. By this treatment, at the time of the etching of the first insulation layer, the top surface of the gate electrode is not excessively removed. In addition, at the time of the etching of the first insulation layer, the side walls are not excessively removed.

The first insulation layer is preferably a silicon nitride film or a silicon oxide nitride film. The first insulation layer may be of a laminated structure having a silicon oxide film as a lower layer and a silicon nitride film or a silicon oxide nitride film as an upper layer.

The thickness of the first insulation layer is preferably from 70 to 200 nm.

When the first insulation layer is of the above-described laminated structure, the thickness of the silicon oxide film serving as the lower layer is preferably from 5 to 50 nm, and the thickness of the silicon nitride film or silicon oxide nitride film serving as the upper layer is preferably from 70 to 190 nm.

The second insulation layer is preferably formed of a silicon oxide film.

The thickness of the second insulation layer is preferably from 70 to 190 nm.

The second insulation layer may be of a two-layered structure having a silicon oxide film as a lower layer and a silicon nitride film or a silicon oxide nitride film as an upper layer. In this case, in the second insulation layer, the thickness of the silicon oxide film serving as the lower layer is preferably from 5 to 25 nm, and the thickness of the silicon nitride film or silicon oxide nitride film serving as the upper layer is preferably from 70 to 190 nm.

According to a preferred embodiment of the present invention, there is the relationship h=5 W, T≧h, and W≧20 nm, where W represents the width of the side wall spacers in the vicinity of contact with the gate insulation film, h represents the height of the side wall spacers, and T represents the height of the gate electrode.

With such a structure, even if the height of the gate electrode is made low, a sufficient distance is secured between the gate electrode and the source-drain regions on the surfaces of the side wall spacers.

The above silicide layers are preferably silicide layers of Ti (titanium), Co (cobalt), or Ni (nickel).

There may be a further step of forming, above the semiconductor substrate, an interlayer insulation film in a single layer or in two layers.

In a method for producing a semiconductor device according to another aspect of the present invention, first, on a surface of a semiconductor substrate, an element separating region for separating an element region from other element regions is formed. Next, above the semiconductor substrate via a gate insulation film, a gate electrode having a first insulation layer formed on the top surface of the gate electrode is formed. On the semiconductor substrate, a second insulation layer is formed in such a manner that the side walls of the gate electrode and the top surface of the first insulation layer are covered. The second insulation layer is etched back in order to form side wall spacers on the side walls of the gate electrode and to expose a surface of the element region. With use of the gate electrode and the side wall spacers as masks, impurity ions are implanted into the element region in order to form a pair of source-drain regions on the surface of the semiconductor substrate and at both sides of the gate electrode. A first high-melting-point metal film is formed in such a manner that the surfaces of the pair of source-drain regions are covered, and heat treatment is carried out in order to form a first silicided layer on the surfaces of the source-drain regions, and thereafter, not-yet reacted first high-melting-point metal film is removed. Above the semiconductor substrate, an interlayer insulation film is formed in such a manner that the gate electrode provided with the first insulation layer is covered. A surface of the interlayer insulation film is polished in order to flatten the surface thereof, and the surface of the first insulation layer is exposed. The exposed first insulation layer is removed in order to expose the top surface of the gate electrode. On the interlayer insulation film, a second high-melting-point metal film is formed in such a manner that the exposed top surface of the gate electrode is covered, and heat treatment is carried out in order to form a second silicided layer on the top surface of the gate electrode. Contact holes are formed in the interlayer insulation film, and metal wiring lines are formed.

According to this invention, since an interlayer insulation film is provided in such a manner that the side wall spacers are covered, and siliciding treatment is carried out on the gate electrode surface, the occurrence of short circuiting between the gate electrode surface and the source-drain regions is prevented.

The first insulation layer preferably contains a silicon nitride film or a silicon oxide nitride film.

The first insulation layer may be of a laminated structure having a silicon oxide film as a lower layer and a silicon nitride film or a silicon oxide nitride film as an upper layer.

The thickness of the silicon nitride film or silicon oxide nitride film in the first insulation layer is preferably from 100 to 250 nm.

When the first insulation layer is of the above-described laminated structure, the thickness of the silicon oxide film serving as the lower layer is preferably from 5 to 50 nm, and the thickness of the silicon nitride film or silicon oxide nitride film serving as the upper layer is preferably from 70 to 190 nm.

The second insulation layer is preferably a silicon oxide film.

The thickness of the silicon oxide film serving as the second insulation layer is preferably from 70 to 190 nm.

The second insulation layer may be of a two-layered structure having a silicon oxide film as a lower layer and a silicon nitride film or a silicon oxide nitride film as an upper layer. In this case, the thickness of the silicon oxide film serving as the lower layer is preferably from 5 to 25 nm, and the thickness of the silicon nitride film or silicon oxide nitride film serving as the upper layer is preferably from 70 to 190 nm.

If the amount of polishing of the surface of the interlayer insulation film is such that 5 to 80% of thickness of the first insulation film is also polished, the protrusions at the top of the side wall spacers are eliminated.

A semiconductor device according to another aspect of the present invention is concerned with a semiconductor device comprising: a semiconductor substrate; a gate electrode formed above the semiconductor substrate via a gate insulation film; a pair of source-drain regions formed on a surface of the semiconductor substrate and at both sides of the gate electrode; side wall spacers formed on the side walls of the gate electrode; and silicided layers formed on the top surface of the gate electrode and on surfaces of the source-drain regions. There is the relationship h=5 W, T≧h, and W≧20 nm, where W represents the width of the side wall spacers in the vicinity of contact with the gate insulation film, h represents the height of the side wall spacers, and T represents the height of the gate electrode.

A semiconductor device according to another aspect of the present invention is concerned with a semiconductor device comprising: a semiconductor substrate; a gate electrode formed above the semiconductor substrate via a gate insulation film; a pair of source-drain regions formed on a surface of the semiconductor substrate and at both sides of the gate electrode; side wall spacers formed on the side walls of the gate electrode; and silicided layers formed on the top surface of the gate electrode and on surfaces of the source-drain regions. The thickness of a silicided layer formed on a surface of the gate electrode is thicker than the thickness of a silicided layer formed on the surfaces of the source-drain regions.

Each of the side wall spacers may be of a two-layered structure including a lower layer which is in contact with the side walls of the gate electrode and which is formed of a silicon oxide film, and an upper layer which is provided at the side walls of the gate electrode via the lower layer and which is formed of a silicon nitride film or a silicon oxide nitride film.

According to the method of producing a semiconductor device according to the present invention, at the time of forming a silicide region and a non-silicide region simultaneously, on the side surfaces of the gate electrode, side wall spacers are formed with more than a predetermined width being secured. For this reason, at the time of silicidation annealing treatment, even if the diffusion of silicon from the source-drain regions occurs in the high-melting-point metal film, because of a sufficient side wall width, short circuiting, which is due to the silicided layer, between the gate electrode and the source-drain regions is inhibited. Thus, the thinning of the gate electrode is made possible, the fining of the device structure can be dealt with, and the high integration of the semiconductor device is made possible.

### BRIEF DESCRIPTION OF THE DRAWINGS

FIG. 1 is a cross sectional view of a semiconductor device in steps (A)-(D) of a method of a semiconductor device according to embodiment 1.

FIG. 2 is a cross sectional view of a semiconductor device in steps (E)-(H) of a method of a semiconductor device according to embodiment 1.

FIG. 3 is a cross sectional view of a semiconductor device in steps (I)-(K) of a method of a semiconductor device according to embodiment 1.

FIG. 4 is a cross sectional view of a semiconductor device in steps (L)-(M) of a method of a semiconductor device according to embodiment 1.

FIG. 5 is a cross sectional view of a semiconductor device in steps (A)-(D) of a method of a semiconductor device according to embodiment 2.

FIG. 6 is a cross sectional view of a semiconductor device in steps (E)-(H) of a method of a semiconductor device according to embodiment 2.

FIG. 7 is a cross sectional view of a semiconductor device in steps (I)-(L) of a method of a semiconductor device according to embodiment 2.

FIG. 8 is a cross sectional view of a semiconductor device in steps (M)-(O) of a method of a semiconductor device according to embodiment 2.

FIG. 9 is a cross sectional view of a semiconductor device according to embodiment 3.

FIG. 10 is a cross sectional view of a semiconductor device in steps (A)-(B) of a method of a semiconductor device according to embodiment 4.

FIG. 11 is a cross sectional view of a semiconductor device in steps (A)-(D) of a method of a semiconductor device according to embodiment 5.

FIG. 12 is a cross sectional view of a semiconductor device in steps (E)-(G) of a method of a semiconductor device according to embodiment 5.

FIG. 13 is a cross sectional view of a semiconductor device in steps (A)-(D) of a method of a semiconductor device according to embodiment 6.

FIG. 14 is a cross sectional view of a semiconductor device in steps (A)-(D) of a conventional method of a semiconductor device.

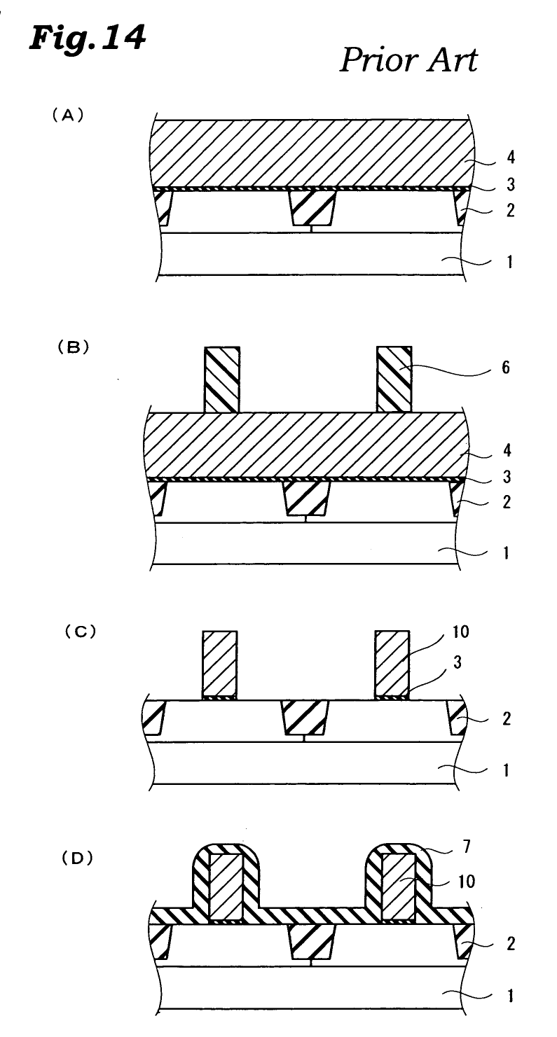

FIG. 15 is a cross sectional view of a semiconductor device in steps (E)-(H) of a conventional method of a semiconductor device.

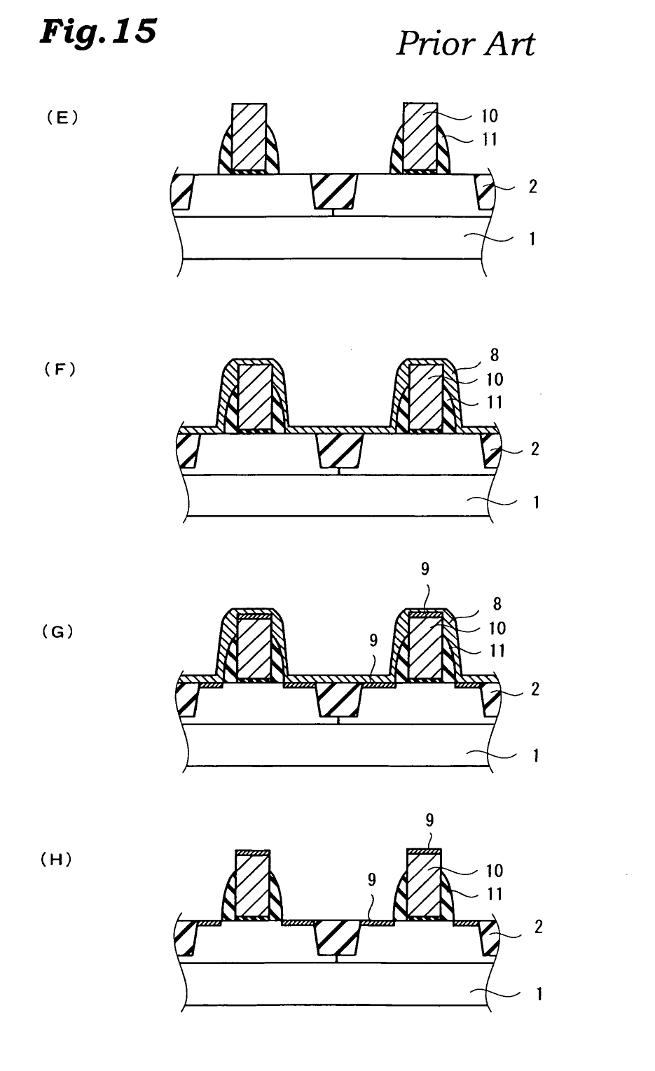

FIG. 16 is a cross sectional view of a semiconductor device in steps (A)-(D) of another conventional method of a semiconductor device.

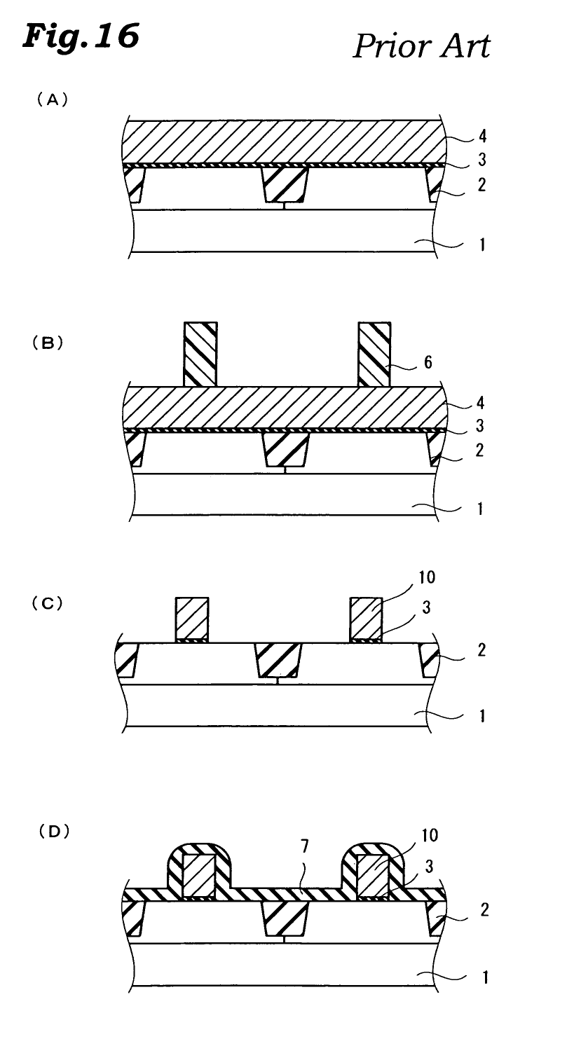

FIG. 17 is a cross sectional view of a semiconductor device in steps (E)-(H) of another conventional method of a semiconductor device.

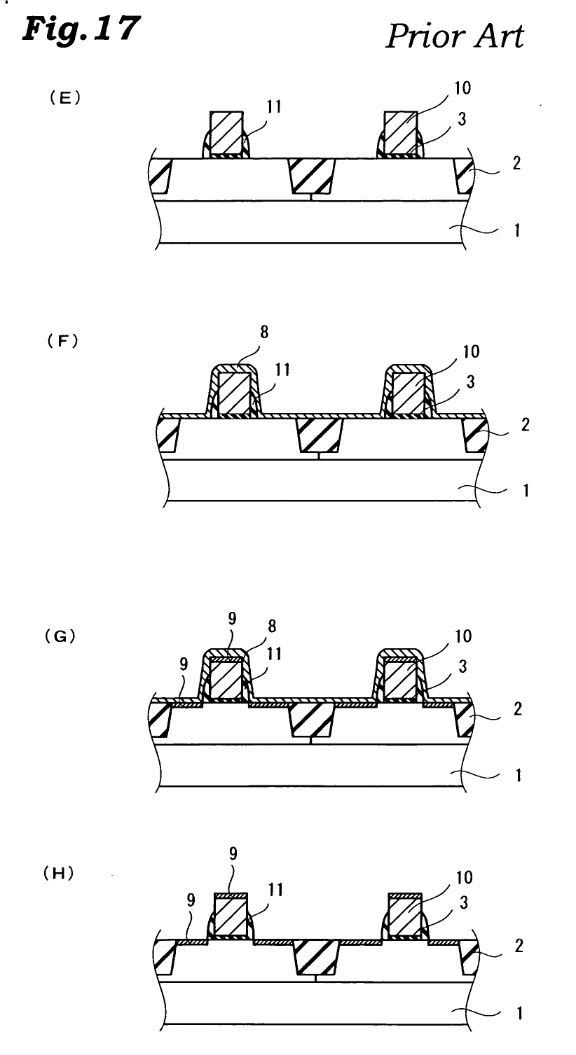

FIG. 18 is a cross sectional view of a semiconductor device in steps (A)-(D) of still another conventional method of a semiconductor device.

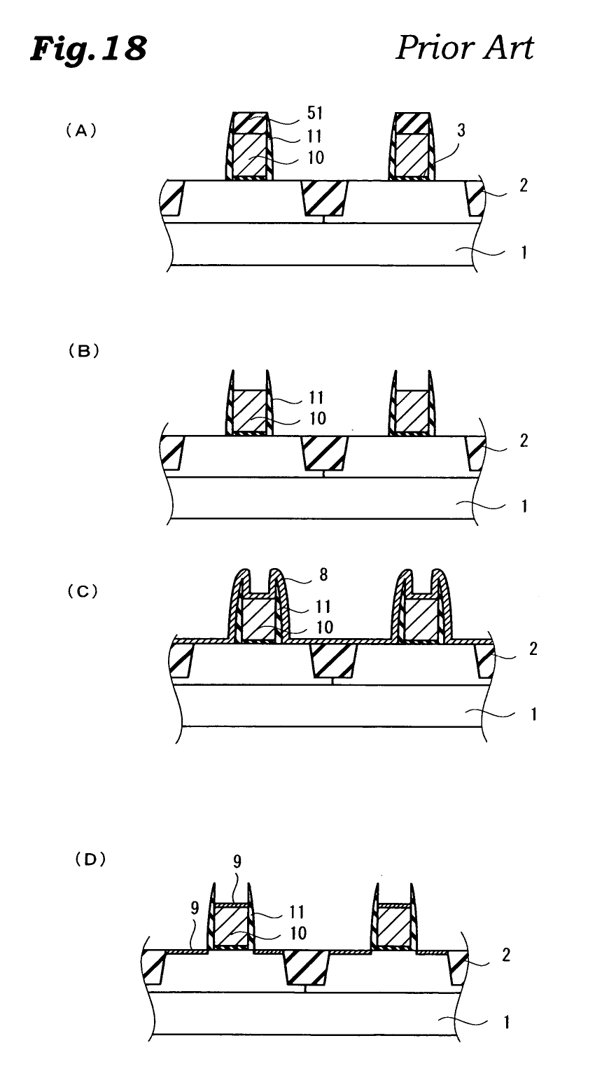

In the figures, reference numeral 1 denotes a semiconductor substrate, 2 denotes an element separating region, 3 denotes a gate insulation layer, 4 denotes a polysilicon layer, 5 denotes a first insulation layer, 6 denotes a resist pattern, 7 denotes a second insulation layer, 8 denotes a high-melting-point metal film, 9 denotes a silicided layer, 10 denotes a gate electrode, 11 denotes a side wall spacer, 13 denotes a first interlayer insulation film, 14 denotes a metal wiling line, 15 denotes a contact hole, and 16 denotes a second interlayer insulation film.

### DESCRIPTION OF THE PREFERRED EMBODIMENTS

Embodiments of the present invention will be described below by reference to drawings. In the figures below, identical or corresponding parts are given the same reference numeral.

### Embodiment 1

Embodiment 1 is the case where the silicidation of the surface of the gate electrode and the silicidation of the source-drain regions are carried out simultaneously.

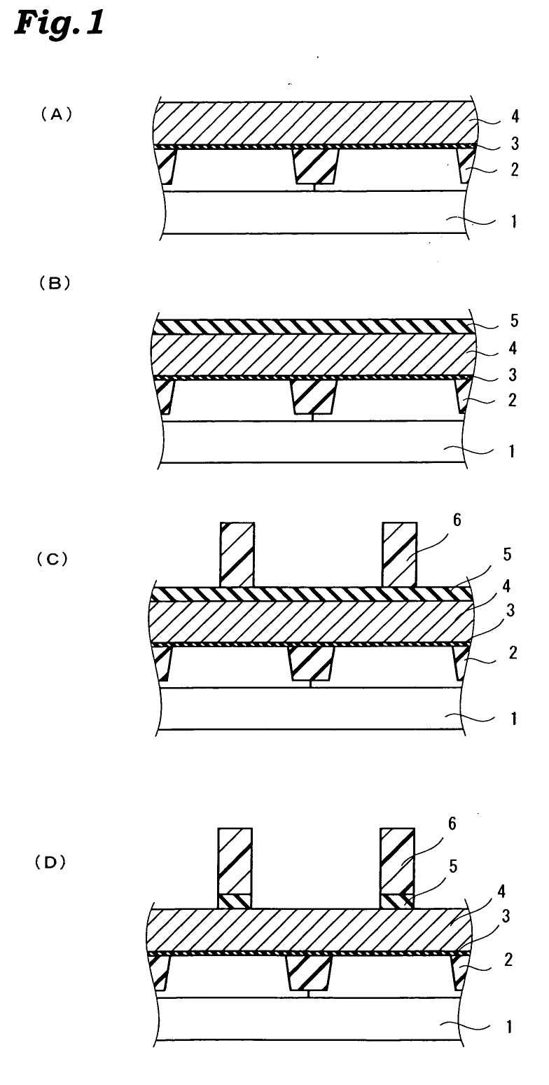

Referring to FIG. 1(A), similarly to the prior art, by providing, on the surface of a silicon substrate that is semiconductor substrate 1, element separating region 2, a plurality of divided element regions are formed. Next, above semiconductor substrate 1, gate insulation film 3 and polysilicon layer 4 are accumulated.

Referring to FIG. 1(B), on polysilicon layer 4, first insulation layer 5 is accumulated. As first insulation layer 5, a silicon nitride film is used. The thickness of first insulation layer 5 is desirably 1400 Å. With such a structure, as described later, at the time of etching polysilicon layer 4 and gate insulation film 3, all of first insulation layer 5 is not etched. In addition, at the time of etching second insulation layer 7 that will be described later, all of first insulation layer 5 is not etched. In addition, at the time of silicidation annealing treatment, even if the diffusion of silicon from the source-drain regions occurs in the high-melting-point metal film on the surfaces of side wall spacers 11, a sufficient width is secured for side wall spacers 11 such that the silicided layer that causes short circuiting between gate electrode 10 and the source-drain regions is not formed on the surfaces of side wall spacers 11.

Referring to FIGS. 1(C) and 1(D), on the surface of first insulation layer 5 that corresponds to the portion on which a gate electrode is formed, resist pattern 6 is formed by the lithography technique. Next, using resist pattern 6 as a mask, first insulation layer 5 is subjected to anisotropic etching by using, for example, a magnetron RIE (Reactive Ion Etching) apparatus and under the following conditions.

Pressure: 50 mTorr

High-frequency power: 500 W

CH₂F₂/Ar/O₂=40/30/15 sccm

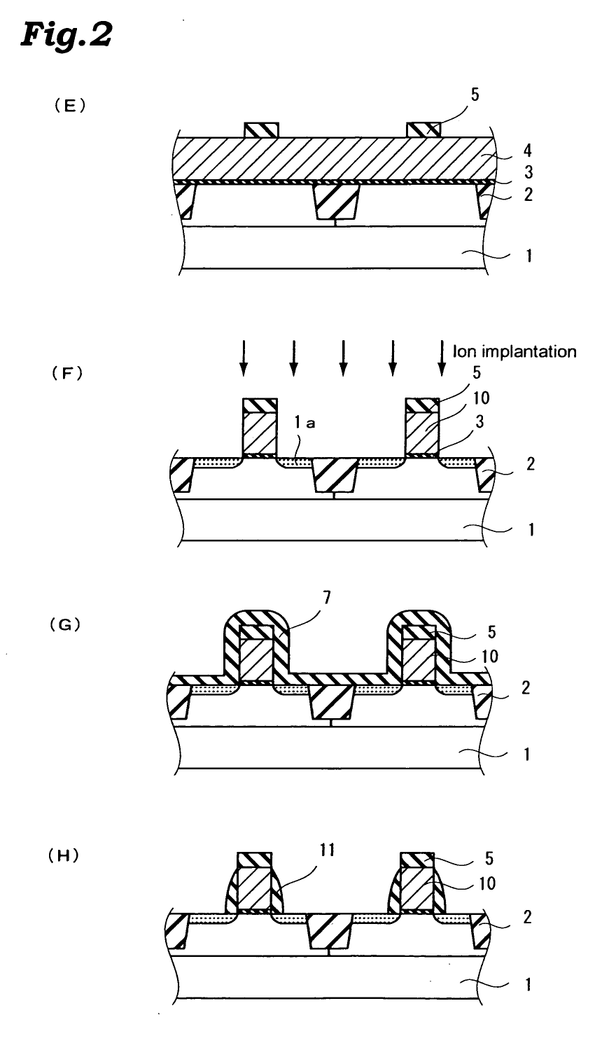

Referring to FIGS. 1(D) and 2(E), by using an ashing apparatus, resist pattern 6 is removed.

Referring to FIGS. 2(E) and 2(F), using remaining first insulation layer 5 as an etching mask, the portions of polysilicon layer 4 and gate insulation film 3 other than the portions at the mask are etched, thereby forming gate electrode 10. Next, ion implantation for forming LDD region 1a of a transistor is carried out.

Referring to FIG. 2(G), as second insulation layer 7, a silicon oxide film is accumulated on semiconductor substrate 1 in such a manner that formed gate electrode 10 and remaining first insulation layer 5 are covered. Referring to FIGS. 2(G) and 2(H), by etching back second insulation layer 7, on the side walls of gate electrode 10, side wall spacers 11 of silicon oxide film are left. The width of side wall spacers 11 obtained by etching-back (the width of side wall spacers 11 in the vicinity of contact with processed gate insulation film 3) is, in the case of using only a silicon oxide film for second insulation layer 7, approximately from 17 to 20 nm. The height of side wall spacers 11 is approximately five times the width of side wall spacers 11 and approximately equal to the height of gate electrode 10 (including the thickness of first insulation layer 5).

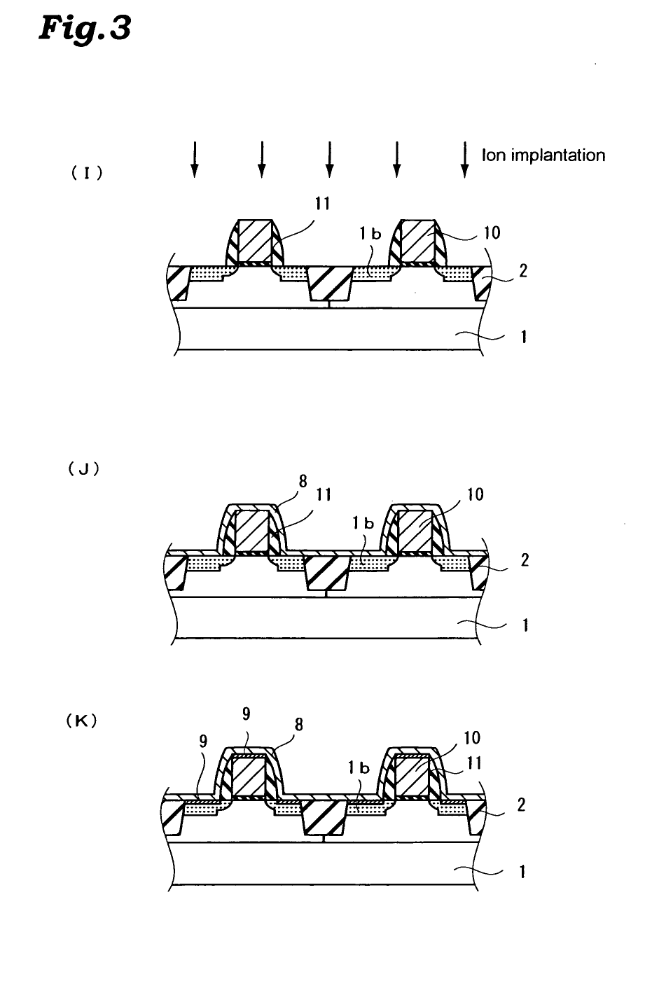

Referring to FIGS. 2(H) and 3(I), remaining first insulation layer 5 is removed. Next, in order to form a highly dense N region that constitutes source-drain regions 1b of the transistor, ion implantation of arsenic or the like is carried out, and heat treatment is carried out in order to activate the implanted arsenic ions.

Referring to FIG. 3(J), by accumulating a high-melting-point metal such as Ti (titanium), Co (cobalt), and Ni (nickel) by sputtering method, plating method, or CVD method, high-melting-point metal 8 is formed over the entire surface of semiconductor substrate 1. Next, referring to FIG. 3(K), by carrying out silicidation annealing treatment by suitable heat treatment, the surface of gate electrode 10, the surfaces of source-drain regions 1b, and high-melting-point metal film 8 are allowed to react, and thus, silicided layers 9 are formed.

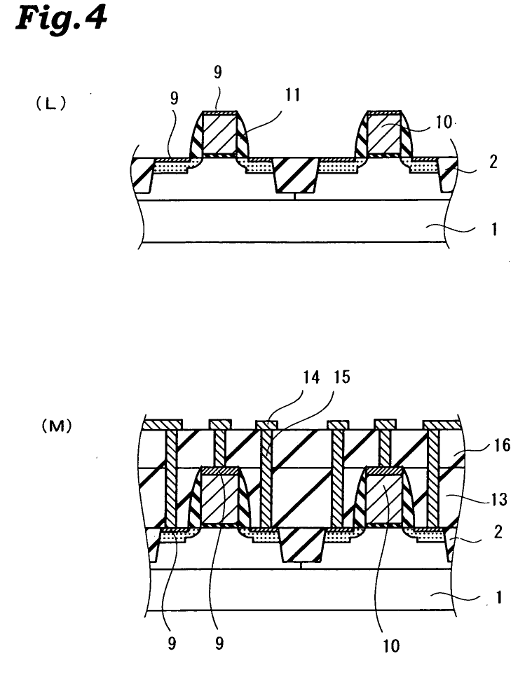

Referring to FIGS. 3(K) and 4(L), not-yet-reacted high-melting-point metal film of high-melting-point metal film 8 is removed by selective etching. By the above steps, a silicided region and a non-silicided region are formed simultaneously.

Referring to FIG. 4(M), above semiconductor substrate 1, first interlayer insulation film 13 and second interlayer insulation film 16 are formed, and in first and second interlayer insulation films 13 and 16, contact holes 15 that expose the surfaces of silicided layers 9 are formed, and by providing metal wiring lines 14, a semiconductor device is completed.

According to the present embodiment, at the time of silicidation annealing treatment in the step of FIG. 3(K), even if the diffusion of silicon from the source-drain regions occurs in high-melting-point metal film 8 on side wall spacers 11, since there is a sufficient width for side wall spacers 11, short circuiting, which is due to the silicided layer, between gate electrode 10 and source-drain regions 1b is controlled.

### Embodiment 2

The present embodiment is the case where the silicidation of the surface of the gate electrode and the silicidation of the source-drain regions are carried out in different steps.

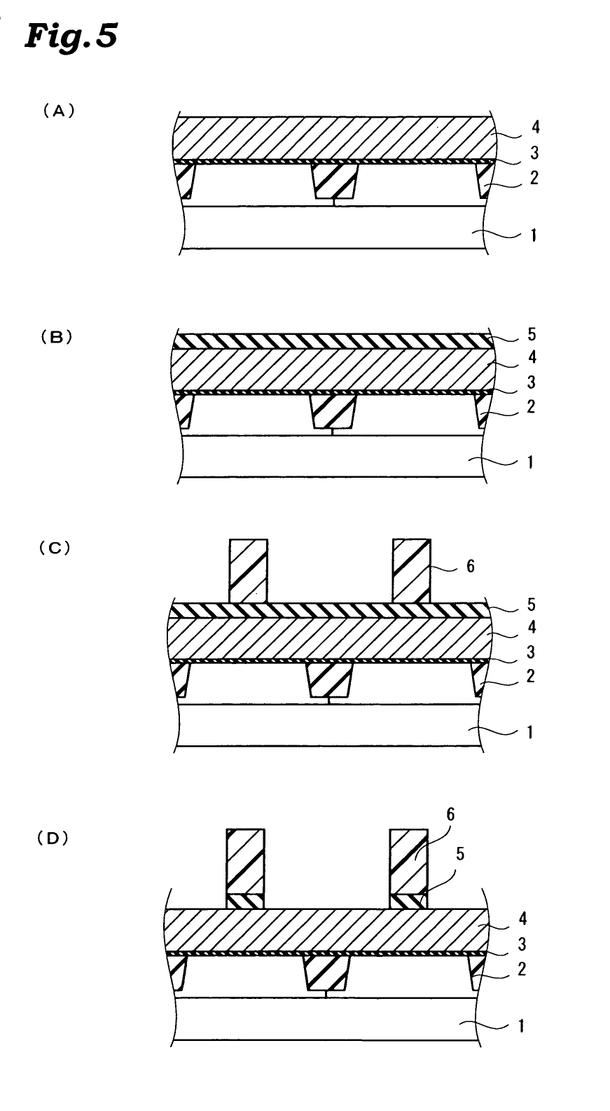

Referring to FIG. 5(A), similarly to embodiment 1, by providing, on the surface of semiconductor substrate 1, element separating region 2, a plurality of divided element regions are formed. Above semiconductor substrate 1, gate insulation film 3 and polysilicon layer 4 are accumulated.

Referring to FIG. 5(B), on polysilicon layer 4, first insulation layer 5 is accumulated. As first insulation layer 5, a silicon oxide film, silicon nitride film, or silicon nitride oxide film is used. Also, first insulation layer 5 may be of a laminated structure such that a silicon oxide film is grown at from 5 to 50 nm on polysilicon layer 4, and thereon, a silicon nitride film or a silicon nitride oxide film is grown at from 70 to 190 nm.

Next, referring to FIGS. 5(C) and 5(D), on first insulation layer 5 that corresponds to the portion on which a gate electrode is formed, resist pattern 6 is formed by the lithography technique. Next, using resist pattern 6 as a mask, first insulation layer 5 is subjected to anisotropic etching by using, for example, a magnetron RIE (Reactive Ion Etching) apparatus.

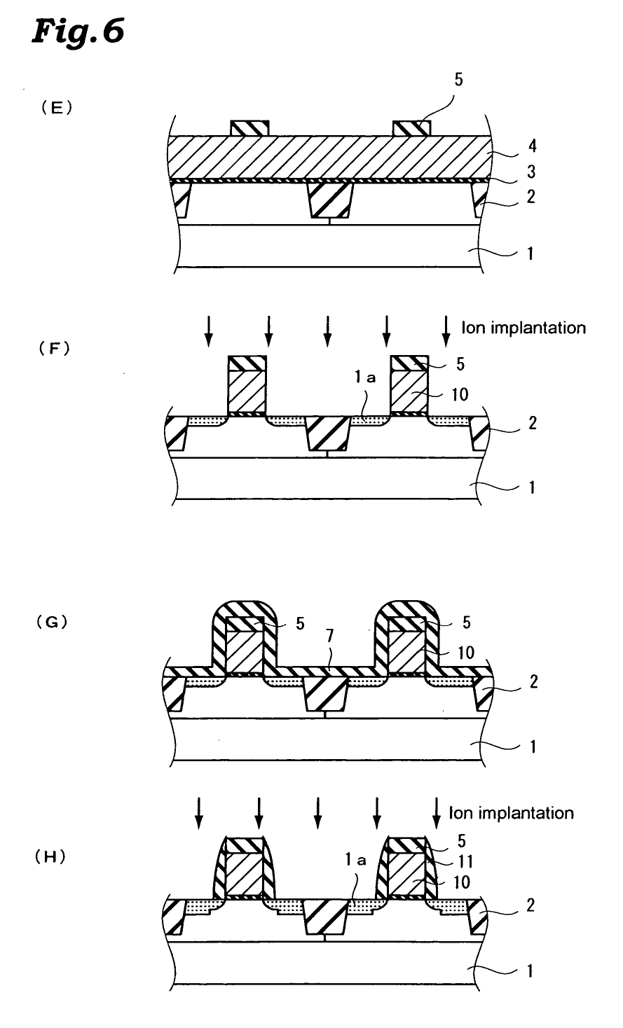

Then, referring to FIGS. 5(D) and 6(E), by using an ashing apparatus and a cleaning apparatus, resist pattern 6 is removed.

Next, referring to FIGS. 6(E) and 6(F), using remaining first insulation layer 5 as an etching mask, the portions of polysilicon layer 4 and gate insulation film 3 other than the portions at the mask are etched, thereby forming gate electrode 10. Next, ion implantation for forming LDD region 1a of a transistor is carried out.

Further, referring to FIG. 6(G), as second insulation layer 7, a silicon oxide film, silicon nitride film, or silicon oxide nitride film is accumulated on semiconductor substrate 1 in such a manner that gate electrode 10 and remaining first insulation layer 5 are covered.

Referring to FIGS. 6(G) and 6(H), by etching back second insulation layer 7, on the side walls of gate electrode 10, side wall spacers 11 of silicon oxide film are formed. Since second insulation layer 7 includes a silicon oxide nitride film or a silicon nitride film, the width of side wall spacers 11 (the width of side wall spacers 11 in the vicinity of contact with processed gate insulation film 3) is, even if etched back, formed wider than when using only a silicon oxide film for second insulation layer 7.

Next, as shown in FIG. 6(H), in order to form a highly dense N region for source-drain regions 1b of the transistor, ion implantation of arsenic or the like is carried out, and heat treatment is carried out in order to activate the implanted arsenic ions.

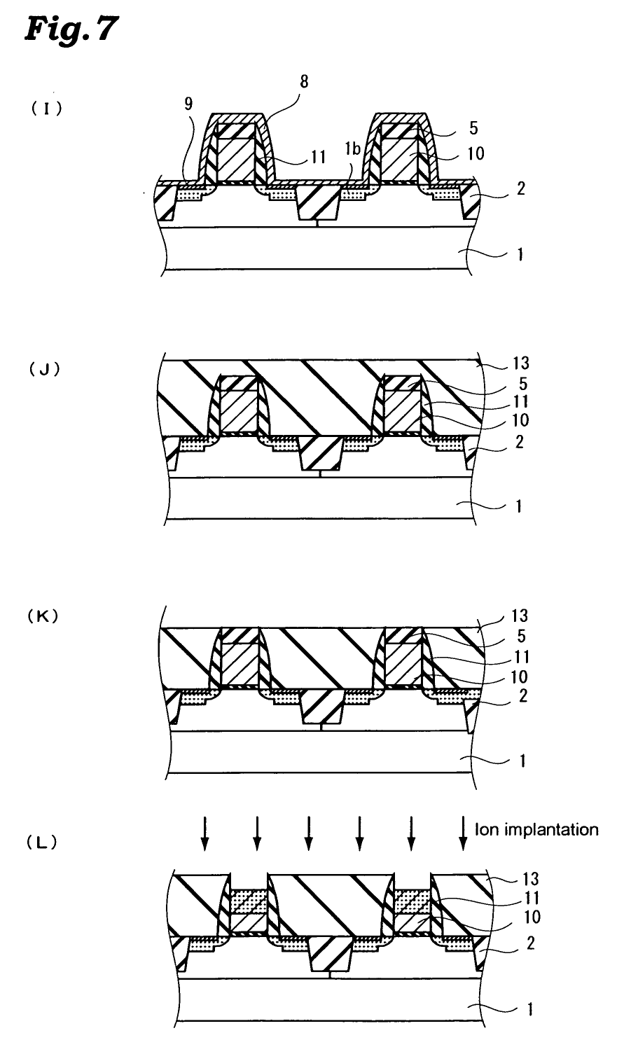

Then, as shown in FIG. 7(I), using a high-melting-point metal such as Ti (titanium), Co (cobalt), and Ni (nickel), high-melting-point metal 8 of from 10 to 100 nm is accumulated over the entire surface of semiconductor substrate 1 by sputtering method, plating method, or CVD method. Next, by carrying out first silicidation annealing treatment by a heat treatment step of from 450 to 650° C., semiconductor substrate 1 and high-melting-point metal film 8 are allowed to react, and thus, silicided layer 9 is formed on source-drain regions 1b. Then, not-yet-reacted high-melting-point metal film of high-melting-point metal film 8 is removed by selective etching.

Next, referring to FIG. 7(J), on semiconductor substrate 1, first interlayer insulation film 13 is formed at approximately from 300 to 800 nm. Referring to FIG. 7(K), flattening treatment is carried out by polishing first interlayer insulation film 13. As a stopper film for the polishing, in the element formation region, first insulation layer 5, which is formed on gate electrode 10, exhibits the effect of the film. The stopper film has a material similar to first insulation layer 5, and is also formed on a peripheral portion of semiconductor substrate 1 and on the element separating region. At this occasion, the amount of polishing of first insulation layer 5 is controlled to approximately from 2 to 20% of the thickness of first insulation layer 5.

Subsequently, referring to FIGS. 7(K) and 7(L), first insulation layer 5 is removed. As a result, a semiconductor device in which side wall spacers 11 with height being higher than gate electrode 10 are left is formed. It is noted that if first insulation layer 5 is formed only of a silicon oxide film, side wall spacers 11 with height being shorter than gate electrode 10 are formed. Then, in order to form a highly dense N region in gate electrode 10, ion implantation of arsenic or the like is carried out, and heat treatment is carried out in order to activate the implanted arsenic ions.

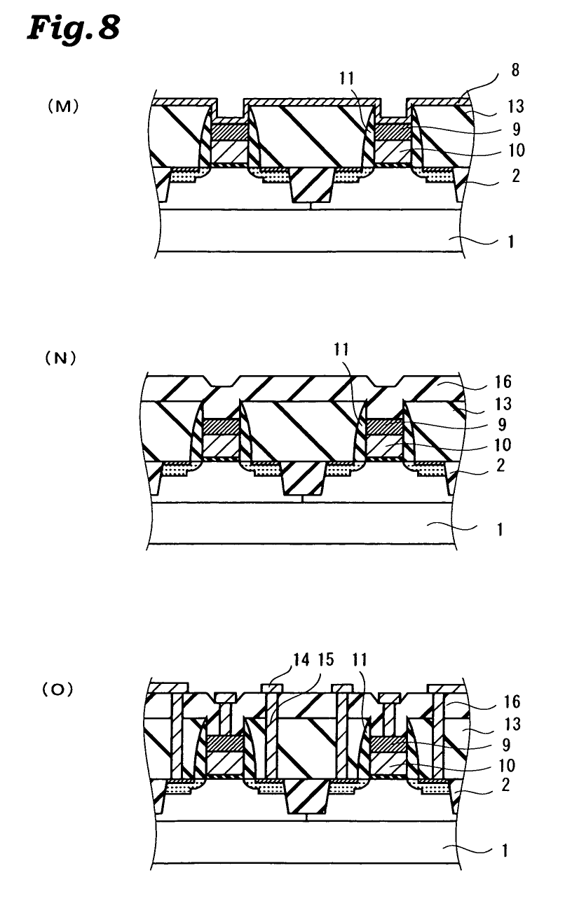

Next, as shown in FIG. 8(M), if a high-melting-point metal such as Ti (titanium), Co (cobalt), and Ni (nickel) is accumulated by sputtering method, plating method, or CVD method, high-melting-point metal 8 is formed over the entire surface of semiconductor substrate 1. Next, by carrying out silicidation annealing treatment by a heat treatment step of from 450 to 650° C., polysilicon layer, which is gate electrode 10, and high-melting-point metal film 8 are allowed to react, and thus, silicided layer 9 is formed on the surface of gate electrode 10. Next, not-yet-reacted high-melting-point metal film of high-melting-point metal film 8 is removed by selective etching.

The silicidation of the surface of the gate electrode of a transistor is conventionally carried out simultaneously with the silicidation of the source-drain regions, and because the depth of the source-drain regions is made shallow, sufficient silicidation cannot be carried out. Accordingly, a reduction in the resistance of polysilicon for the gate electrode has been insufficient. According to the present embodiment, since the thickness of the high-melting-point metal film can be selected independently, and the heat treatment temperature can be selected at a high value, a reduction in the resistance of the polysilicon gate electrode involved in the upcoming fining can be easily accomplished.

In addition, the conventional silicidation treatment is such that in the high-melting-point metal film on the surfaces of the side wall spacers, at the time of heat treatment, silicon diffuses and migrates from the source-drain, thereby generating a silicided layer, and as a result, with the surfaces of the side wall spacers as current pathways, short-circuiting is caused between the surface of the gate electrode and the source-drain regions. However, according to embodiment 2, since the surfaces of side wall spacers 11 are covered by first interlayer insulation film 13, and then the silicidation treatment of the top surface of the gate electrode is carried out, the effect of efficiently preventing the occurrence of short circuiting between the gate electrode surface and the source-drain regions is obtained.

Next, referring to FIG. 8(N), second interlayer insulation film 16 is formed above semiconductor substrate 1 at a thickness of from 50 to 250 nm.

Next, referring to FIG. 8(O), after forming contact holes 15 in first interlayer insulation film 13 and second interlayer insulation film 16, metal wiling lines 14 are formed, thus forming a transistor. Subsequently, a further interlayer insulation film can be formed, or a surface protection film can be formed to complete a semiconductor device.

### Embodiment 3

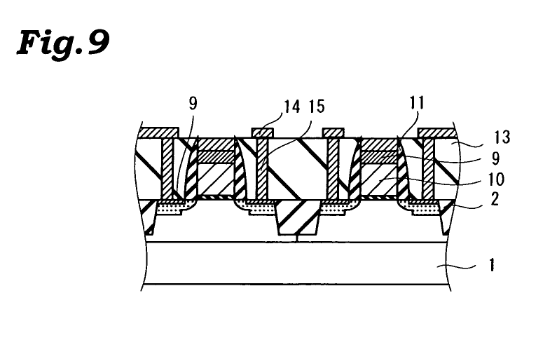

Embodiment 3 is concerned with a modified example of embodiment 2. While in embodiment 2 the case where a two-layered structure is used for the interlayer insulation film has been described, a single-layered structure may be used as shown in FIG. 9. Such a semiconductor device is formed such that in the step of FIG. 8(M), after removing not-yet-reacted high-melting-point metal film, contact holes 15 and metal wiling lines 14 are formed directly in first interlayer insulation film 13.

### Embodiment 4

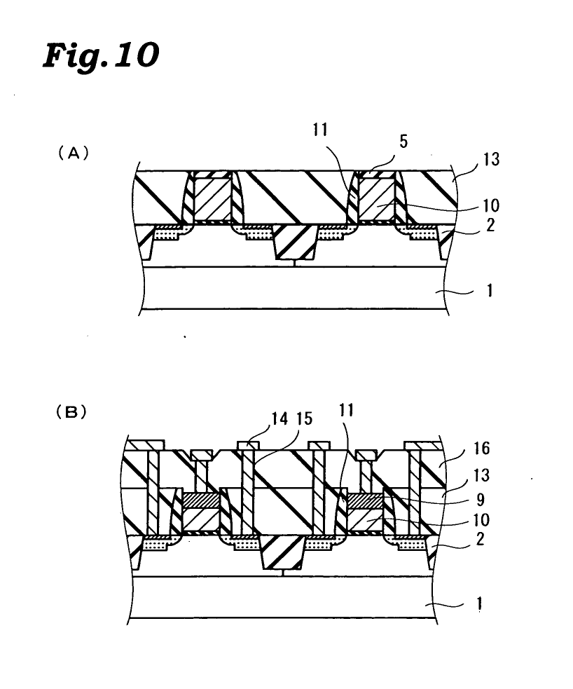

Embodiment 4 is concerned with a further modified example of embodiment 2. First, the same steps as the steps of FIGS. 5(A)-(D), FIGS. 6(E)-(H), and FIGS. 7(I)-(J) are carried out. Next, referring to FIGS. 7(J) and 10(A), flattening treatment is carried out such that first interlayer insulation film 13 is polished in such a manner that 20 to 80% of thickness of first insulation layer 5 is polished.

According to the present embodiment, at the time of the flattening treatment of first interlayer insulation film 13, the protrusions at the top of side wall spacers 11 are removed, and at the time of first silicidation annealing treatment, conductive pieces of high-melting-point metal film 8 and silicide powder that are left on the upper surfaces of side wall spacers 11 are removed. As a result, short circuiting that is caused by the foregoing between the silicided layer 9 on the surface portion of the gate electrode and the source region or drain region of the transistor is prevented.

Then, the same steps as the steps of FIGS. 7(L), 8(M), and 8(N) are carried out. Referring to FIG. 10(B), second interlayer insulation film 16 is formed above semiconductor substrate 1 at a thickness of from 50 to 250 nm. Next, after forming contact holes 15 in first interlayer insulation film 13 and second interlayer insulation film 16, metal wiling lines 14 are formed, thus completing a transistor.

### Embodiment 5

The present embodiment is concerned with a further modified example of embodiment 2. In the present embodiment, each of the side wall spacer is of a two-layered structure. First, the same steps as the steps of FIGS. 5(A)-(D) and FIGS. 6(E)-(F) are carried out.

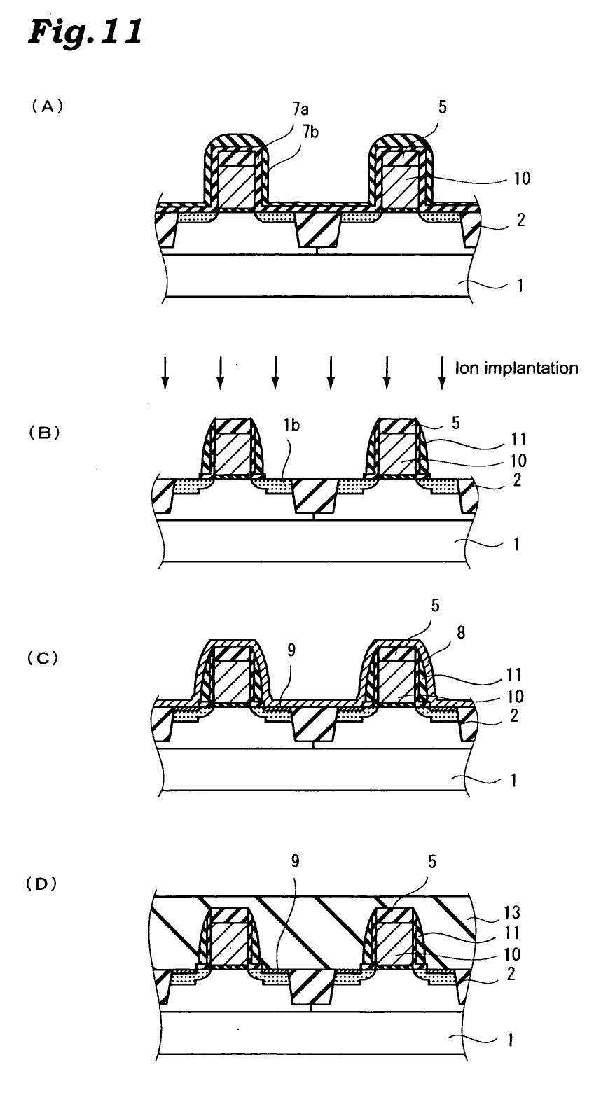

Next, referring to FIG. 11(A), silicon oxide film 7a is formed on semiconductor substrate 1 in such a manner that gate electrode 10 and remaining first insulation layer 5 are covered, and further thereon, silicon oxide nitride film (or silicon nitride film) 7b is accumulated. The thickness of silicon oxide film 7a, which is the lower layer, is from 5 to 25 nm, and the thickness of silicon oxide nitride film (or silicon nitride film) 7b, which is the upper layer, is from 70 to 190 nm.

Referring to FIGS. 11(A) and 11(B), by etching back silicon oxide nitride film (or silicon nitride film) 7b and silicon oxide film 7a, on the side walls of gate electrode 10, side wall spacers 11 are formed. Since side wall spacers 11 include a silicon oxide nitride film (or a silicon nitride film), the width of side wall spacers 11 (the width of side wall spacers 11 in the vicinity of contact with processed gate insulation film 3) is, even if etched back, formed wider than when using only a silicon oxide film for second insulation layer 7 as shown in FIG. 6(G). Next, in order to form a highly dense N region of source-drain regions 1b of the transistor, ion implantation of arsenic or the like is carried out, and heat treatment is carried out in order to activate the implanted arsenic ions.

Then, as shown in FIG. 11(C), using a high-melting-point metal such as Ti (titanium), Co (cobalt), and Ni (nickel), high-melting-point metal 8 of from 10 to 100 nm is accumulated over the entire surface of semiconductor substrate 1 by sputtering method, plating method, or CVD method. Next, by carrying out a first silicidation annealing treatment by a heat treatment step of from 450 to 650° C., semiconductor substrate 1 and high-melting-point metal film 8 are allowed to react, and thus, silicided layer 9 is formed on source-drain regions 1b. Then, not-yet-reacted high-melting-point metal film of high-melting-point metal film 8 is removed by selective etching.

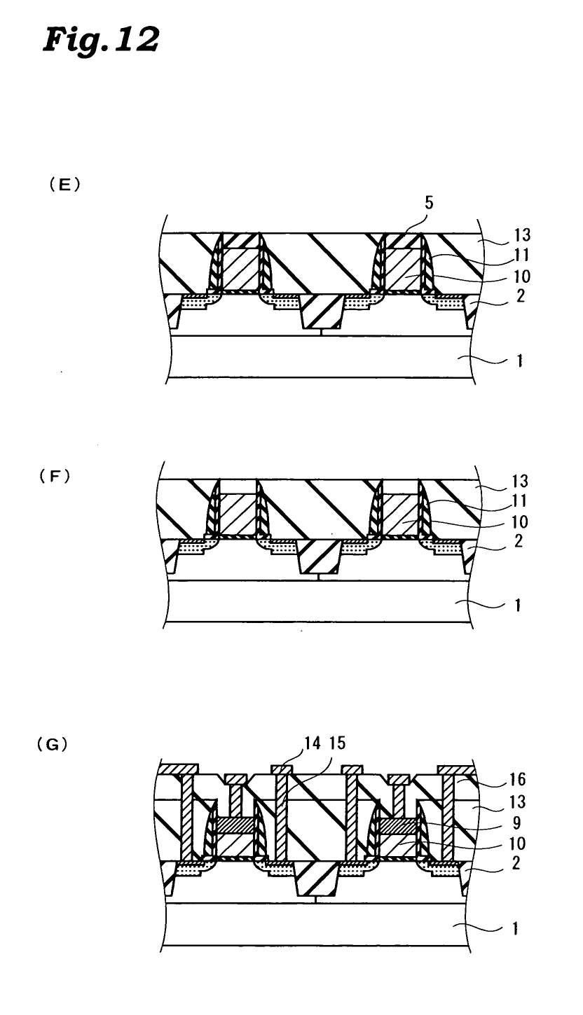

Next, referring to FIG. 11(D), on semiconductor substrate 1, first interlayer insulation film 13 is formed at approximately from 300 to 800 nm. Referring to FIG. 12(E), flattening treatment is carried out by polishing first interlayer insulation film 13. As a stopper film for polishing, in the element formation region, first insulation layer 5, which is formed on gate electrode 10, exhibits the effect of the film. Although not shown, the stopper film has a material similar to first insulation layer 5, and is also formed on a surrounding portion of semiconductor substrate 1 and the element separating region. At this occasion, the amount of polishing of first insulation layer 5 is controlled to approximately from 2 to 20% of the thickness of first insulation layer 5.

Subsequently, referring to FIGS. 12(E) and 12(F), first insulation layer 5 is removed. As a result, a semiconductor device in which side wall spacers 11 with height being higher than gate electrode 10 is formed. Then, the same steps as the steps of FIGS. 7(L), 8(M), and 8(N) are carried out, and silicided layer 9 is formed on gate electrode 10. Next, referring to FIG. 12(G), after forming contact holes 15 in first interlayer insulation film 13 and second interlayer insulation film 16, metal wiring lines 14 are formed, thus forming a transistor.

### Embodiment 6

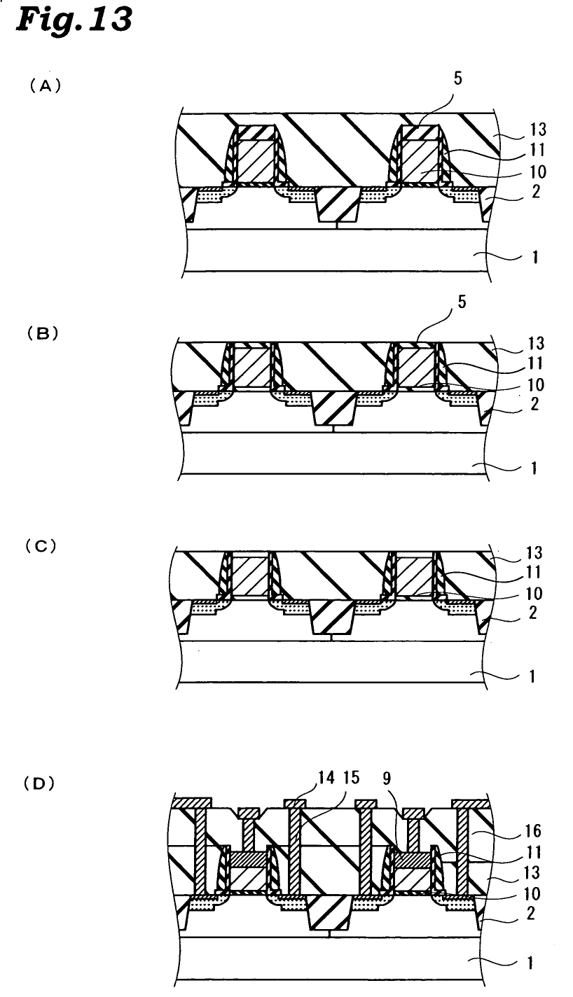

The present embodiment is concerned with a modified example of embodiment 5. FIG. 13(A) corresponds to FIG. 11(D). Referring to FIGS. 13(A) and 13(B), flattening treatment is carried out such that first interlayer insulation film 13 is polished in such a manner that 20 to 80% of thickness of first insulation layer 5 is polished. Then, referring to FIGS. 13(B) and 13(C), first insulation layer 5 is removed.

According to the present embodiment, at the time of the flattening treatment of first interlayer insulation film 13, the protrusions at the top of side wall spacers 11 are removed, and at the time of first silicidation annealing treatment, conductive pieces of high-melting-point metal film 8 and silicide powder that are left on the top portions of side wall spacers 11 are removed. As a result, short circuiting that is caused by the foregoing between the silicided layer 9 on the surface portion of the gate electrode and the source region or drain region of the transistor is prevented.

Then, the same steps as the steps of FIGS. 7(L), 8(M), and 8(N) are carried out, and silicided layer 9 is formed. Referring to FIG. 13(D), second interlayer insulation film 16 is formed above semiconductor substrate 1 at from 50 to 250 nm. Next, after forming contact holes 15 in first interlayer insulation film 13 and second interlayer insulation film 16, metal wiring lines 14 are formed, thus forming a transistor.

By the present invention, the thinning of the gate electrode is made possible, the fining of the device structure can be dealt with, and the high integration of the semiconductor device is made possible.

The Embodiments herein described are to be considered in all respects as illustrative and not restrictive. The scope of the invention should be determined not by the Embodiments illustrated, but by the appended claims, and all changes which come within the meaning and range of equivalency of the appended claims are therefore intended to be embraced therein.

What is claimed is:

1. A method for producing a semiconductor device comprising the steps of:
forming, on a surface of a semiconductor substrate, an element separating region for separating an element region from other element regions;
forming, above the semiconductor substrate via a gate insulation film, a gate electrode having a first insulation layer formed on a top surface of the gate electrode;
forming, on the semiconductor substrate, a second insulation layer in such a manner that side walls of the gate electrode and a top surface of the first insulation layer are covered;
etching back the second insulation layer in order to form side wall spacers on the side walls of the gate electrode and to expose a surface of the element region;
implanting, with use of the gate electrode and the side wall spacers as masks, impurity ions into the surface of the element region in order to form a pair of source-drain regions on the surface of the semiconductor substrate and at both sides of the gate electrode;
removing the first insulation layer off the surface of the gate electrode;
forming, on the surface of the semiconductor substrate, a high-melting-point metal film in such a manner that the top surface of the gate electrode and surfaces of the source-drain regions are covered, and thereafter, carrying out annealing thereby siliciding the top surface of the gate electrode and the surfaces of the source-drain regions in order to form silicide layers; and
removing not-yet reacted high-melting-point metal film.

2. The method for producing a semiconductor device according to claim 1, wherein the first insulation layer is a silicon nitride film or a silicon oxide nitride film.

3. The method for producing a semiconductor device according to claim 1, wherein the first insulation layer is of a laminated structure having a silicon oxide film as a lower layer and a silicon nitride film or a silicon oxide nitride film as an upper layer.

4. The method for producing a semiconductor device according to claim 1, wherein thickness of the first insulation layer is from 70 to 200 nm.

5. The method for producing a semiconductor device according to claim 3, wherein in the first insulation layer, thickness of the silicon oxide film serving as the lower layer is from 5 to 50 nm, and thickness of the silicon nitride film or silicon oxide nitride film serving as the upper layer is from 70 to 190 nm.

6. The method for producing a semiconductor device according to claim 1, wherein the second insulation layer is formed of a silicon oxide film.

7. The method for producing a semiconductor device according to claim 1, wherein thickness of the second insulation layer is from 70 to 190 nm.

8. The method for producing a semiconductor device according to claim 1, wherein in the second insulation layer, a lower layer is a silicon oxide film and an upper layer is a silicon nitride film or a silicon oxide nitride film.

9. The method for producing a semiconductor device according to claim 8, wherein in the second insulation layer, thickness of the silicon oxide film serving as the lower layer is from 5 to 25 nm, and thickness of the silicon nitride film or silicon oxide nitride film serving as the upper layer is from 70 to 190 nm.

10. The method for producing a semiconductor device according to claim 1, there is the relationship h=5 W, T≧h, and W≧20 nm,
where W represents width of the side wall spacers in the vicinity of contact with the gate insulation film, h represents height of the side wall spacers, and T represents height of the gate electrode.

11. The method for producing a semiconductor device according to claim 1, wherein the silicide layers are silicide layers of Ti (titanium), Co (cobalt), or Ni (nickel).

12. The method for producing a semiconductor device according to claim 1, further comprising the step of forming, above the semiconductor substrate, an interlayer insulation film in a single layer or in two layers.

13. A method for producing a semiconductor device comprising the steps of:
forming, on a surface of a semiconductor substrate, an element separating region for separating an element region from other element regions;
forming, above the semiconductor substrate via a gate insulation film, a gate electrode having a first insulation layer formed on a top surface of the gate electrode;
forming, on the semiconductor substrate, a second insulation layer in such a manner that side walls of the gate electrode and a top surface of the first insulation layer are covered;
etching back the second insulation layer in order to form side wall spacers on the side walls of the gate electrode and to expose a surface of the element region;
implanting, with use of the gate electrode and the side wall spacers as masks, impurity ions into the element region in order to form a pair of source-drain regions on the surface of the semiconductor substrate and at both sides of the gate electrode;
forming a first high-melting-point metal film in such a manner that surfaces of the pair of source-drain regions are covered, and carrying out heat treatment in order to form a first silicided layer on the surfaces of the source-drain regions, and thereafter, removing not-yet reacted first high-melting-point metal film;
forming, above the semiconductor substrate, an interlayer insulation film in such a manner that the gate electrode provided with the first insulation layer is covered;
polishing a surface of the interlayer insulation film in order to flatten the surface thereof, and exposing a surface of the first insulation layer;
removing the exposed first insulation film in order to expose the top surface of the gate electrode;
forming, on the interlayer insulation film, a second high-melting-point metal film in such a manner that the exposed top surface of the gate electrode is covered, and carrying out heat treatment in order to form a second silicided layer on the top surface of the gate electrode; and
forming contact holes in the interlayer insulation film, and forming metal wiring lines.

14. The method for producing a semiconductor device according to claim 13, wherein the first insulation layer contains a silicon nitride film or a silicon oxide nitride film.

15. The method for producing a semiconductor device according to claim 13, wherein the first insulation layer is of a laminated structure having a silicon oxide film as a lower layer and a silicon nitride film or a silicon oxide nitride film as an upper layer.

16. The method for producing a semiconductor device according to claim 14, wherein thickness of the silicon nitride film or silicon oxide nitride film in the first insulation layer is from 100 to 250 nm.

17. The method for producing a semiconductor device according to claim 15, wherein in the first insulation layer, thickness of the silicon oxide film serving as the lower layer is from 5 to 50 nm, and thickness of the silicon nitride film or silicon oxide nitride film serving as the upper layer is from 70 to 190 nm.

18. The method for producing a semiconductor device according to claim 13, wherein the second insulation layer is a silicon oxide film.

19. The method for producing a semiconductor device according to claim 18, wherein thickness of the silicon oxide film serving as the second insulation layer is from 70 to 190 nm.

20. The method for producing a semiconductor device according to claim 13, wherein the second insulation layer is of a two-layered structure having a silicon oxide film as a lower layer and a silicon nitride film or a silicon oxide nitride film as an upper layer.

21. The method for producing a semiconductor device according to claim 20, wherein in the second insulation layer, thickness of the silicon oxide film serving as the lower layer is from 5 to 25 nm, and thickness of the silicon nitride film or silicon oxide nitride film serving as the upper layer is from 70 to 190 nm.

22. The method for producing a semiconductor device according to claim 13, wherein amount of polishing of the surface of the interlayer insulation film is such that 5 to 80% of thickness of the first insulation film is also polished.

23. A semiconductor device comprising:
a semiconductor substrate;
a gate electrode formed above the semiconductor substrate via a gate insulation film;
a pair of source-drain regions formed on a surface of the semiconductor substrate and at both sides of the gate electrode;
side wall spacers formed on side walls of the gate electrode; and
silicided layers formed on a top surface of the gate electrode and on surfaces of the source-drain regions,
wherein there is the relationship h=5 W, T≧h, and W≧20 nm,
where W represents width of the side wall spacers in the vicinity of contact with the gate insulation film, h represents height of the side wall spacers, and T represents height of the gate electrode.

24. A semiconductor device comprising:
a semiconductor substrate;
a gate electrode formed above the semiconductor substrate via a gate insulation film;
a pair of source-drain regions formed on a surface of the semiconductor substrate and at both sides of the gate electrode;
side wall spacers formed on side walls of the gate electrode; and
silicided layers formed on a top surface of the gate electrode and on surfaces of the source-drain regions,
wherein thickness of a silicided layer formed on a surface of the gate electrode is thicker than thickness of a silicided layer formed on the surfaces of the source-drain regions.

25. The semiconductor device according to claim 23, wherein each of the side wall spacers is of a two-layered structure including a lower layer which is in contact with the side walls of the gate electrode and which is formed of a silicon oxide film, and an upper layer which is provided at the side walls of the gate electrode via the lower layer and which is formed of a silicon nitride film or a silicon oxide nitride film.
